(19) United States
(12) Patent Application Publication
(10) Pub. No.: US 2013/0017640 A1
(43) Pub. Date: Jan. 17, 2013

(54) METHOD OF PROCESSING OPTICAL DEVICE WAFER

(71) Applicants: Hiroshi Morikazu, Ota-Ku (JP); Yoko Nishino, Ota-ku (JP)

(72) Inventors: Hiroshi Morikazu, Ota-Ku (JP); Yoko Nishino, Ota-ku (JP)

(73) Assignee: DISCO CORPORATION, Tokyo (JP)

(21) Appl. No.: 13/546,219

(22) Filed: Jul. 11, 2012

(30) Foreign Application Priority Data
Jul. 13, 2011 (JP) 2011-154906

(51) Int. Cl. H01L 33/32

(52) U.S. Cl. 438/46; 257/E33.025

(57) ABSTRACT

A method of processing an optical device wafer having an optical device layer including an n-type semiconductor layer and a p-type semiconductor layer stacked over a sapphire substrate, a buffer layer therebetween, allowing peeling of the sapphire substrate. The method includes joining a transfer substrate to the optical device layer, breaking the buffer layer by irradiation with a pulsed laser beam from the sapphire substrate side of the wafer with the transfer substrate joined to the optical device layer, and peeling the sapphire substrate from the optical device wafer with the buffer layer broken, transferring the optical device layer onto the transfer substrate. The pulsed laser beam has a wavelength longer than an absorption edge of the sapphire substrate and shorter than an absorption edge of the buffer layer, and a pulse width set so that a thermal diffusion length will be not more than 200 nm.

### BACKGROUND OF THE INVENTION

1. Field of the Invention

The present invention relates to a method of processing an optical device wafer in which an optical device layer including an n-type gallium nitride semiconductor layer and a p-type gallium nitride semiconductor layer or the like is stacked over a surface of a sapphire substrate, with a buffer layer therebetween, so as to peel the sapphire substrate from the optical device wafer.

2. Description of the Related Art

In an optical device manufacturing process, an optical device wafer is configured by forming optical devices such as light emitting diodes, laser diodes, etc. in a plurality of regions demarcated by a plurality of streets formed in a grid pattern on an optical device layer which includes an n-type semiconductor layer and a p-type semiconductor layer and which is stacked over a surface of a substantially circular disc-shaped sapphire substrate, with a buffer layer therebetween. Subsequently, the optical device wafer is divided along the streets to thereby manufacture the individual optical devices (see, for example, Japanese Patent Laid-open No. Hei 10-305420).

In addition, as a technology for enhancing a cooling effect on optical devices and the luminance of the optical devices, a manufacturing process called lift-off process is disclosed in JP-T-2004-72052. In the disclosed process, a transfer substrate of molybdenum (Mo), copper (Cu), silicon (Si) or the like is joined to an optical device layer, which is stacked over a surface of a sapphire substrate constituting an optical device wafer with a buffer layer therebetween and which includes an n-type semiconductor layer and a p-type semiconductor layer, with a joint metal layer of gold (Au), platinum (Pt), chromium (Cr), indium (In), palladium (Pd) or the like therebetween. Then, the buffer layer is irradiated with a laser beam from the back side of the sapphire substrate, to thereby peel the sapphire substrate. In this manner, the optical device layer is transferred onto the transfer substrate.

### SUMMARY OF THE INVENTION

In this connection, since the buffer layer is as thin as around 1 μm and is formed of the same kind of semiconductor as that forming the optical device layer including the n-type semiconductor layer and the p-type semiconductor layer, it is difficult to break only the buffer layer by irradiation with the laser beam. In addition, since the buffer layer after the peeling of the sapphire substrate has a surface roughness of not less than 250 nm, it may be necessary to polish the surface of the buffer layer. Besides, there is a problem that when a metallic substrate is mounted to the buffer layer side, warpage may be generated in the resulting assembly as a whole, making it difficult to accurately position the condensing point of the laser beam to the buffer layer.

Accordingly, it is an object of the present invention to provide a method of processing an optical device wafer wherein a transfer substrate is joined to an optical device layer stacked over a surface of a sapphire substrate constituting an optical device wafer with a buffer layer therebetween, and thereafter the buffer layer is irradiated with a laser beam from the back side of the sapphire substrate, whereby the buffer layer can be assuredly broken without damaging the optical device layer and the sapphire substrate can be peeled off reliably.

In accordance with an aspect of the present invention, there is provided a method of processing an optical device wafer in which an optical device layer including an n-type semiconductor layer and a p-type semiconductor layer is stacked over a surface of a sapphire substrate, with a buffer layer therebetween, so as to peel the sapphire substrate. The method includes a transfer substrate joining step of joining a transfer substrate to a surface of the optical device layer, a buffer layer breaking step of breaking the buffer layer by irradiation with a pulsed laser beam from the sapphire substrate side of the optical device wafer with the transfer substrate joined to the surface of the optical device layer, and a sapphire substrate peeling step of peeling off the sapphire substrate from the optical device wafer with the buffer layer broken, so as to transfer the optical device layer onto the transfer substrate. The pulsed laser beam for irradiation therewith in the buffer layer breaking step has a wavelength set to be longer than an absorption edge of the sapphire substrate and shorter than an absorption edge of the buffer layer, and a pulse width so set that a thermal diffusion length will be not more than 200 nm.

The buffer layer is preferably formed of gallium nitride (GaN), and the pulse width of the pulsed laser beam for irradiation therewith in the buffer layer breaking step is preferably set to be not more than 200 ps, more preferably not more than 100 ps. In addition, the wavelength of the pulsed laser beam for irradiation therewith in the buffer layer breaking step is preferably set in the range of 150 to 355 nm, more preferably 150 to 250 nm.

In the method of processing an optical device wafer according to the present invention, the pulsed laser beam for irradiation therewith in the buffer layer breaking step has a wavelength set to be longer than the absorption edge of the sapphire substrate and shorter than the absorption edge of the buffer layer, and a pulse width so set that the thermal diffusion length will be not more than 200 nm. This ensures that the energy of the pulsed laser beam is consumed in the buffer layer, and would not damage the optical device layer. In addition, since the thermal diffusion length is as short as 200 nm or below, the energy of the pulsed laser beam is absorbed along the boundary surface with the sapphire substrate in the range of the thermal diffusion length; accordingly, even if the energy distribution is Gaussian distribution, equivalent processing to that in the case of a top-hat shape can be achieved. Furthermore, since the thermal diffusion length is as short as 200 nm or below, the pulsed laser beam is absorbed instantaneously on reaching the buffer layer, in the range of the thermal diffusion length. Therefore, only the buffer layer can be securely broken, even if the sapphire substrate has warpage and the condensing point of the pulsed laser beam is thereby deviated from the buffer layer. Besides, the surface roughness of the buffer layer after the peeling of the sapphire substrate is at a permissible level of 100 nm or below, so that there is no need for an after-treatment such as polishing.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of an optical device wafer to be processed by the method of processing an optical device wafer according to the present invention;

FIG. 1B is a sectional view showing, in an enlarged form, an essential part of the optical device wafer;

FIGS. 2A and 2B illustrate a transfer substrate joining step in the method of processing an optical device wafer according to the present invention;

FIG. 3 illustrates a transfer substrate adhering step in the method of processing an optical device wafer according to the present invention;

FIG. 4 is a perspective view of an essential part of a laser beam processing apparatus for carrying out a buffer layer breaking step in the method of processing an optical device wafer according to the present invention;

FIGS. 5A to 5C illustrate a buffer layer breaking step in the method of processing an optical device wafer according to the present invention;

FIG. 6 illustrates a sapphire substrate peeling step in the method of processing an optical device wafer according to the present invention;

FIG. 7 is a graph showing light transmittance curves of sapphire and gallium nitride (GaN); and

FIG. 8 shows data representing the relationship between thermal diffusion length and pulse width in gallium nitride (GaN).

### DETAILED DESCRIPTION OF THE PREFERRED EMBODIMENTS

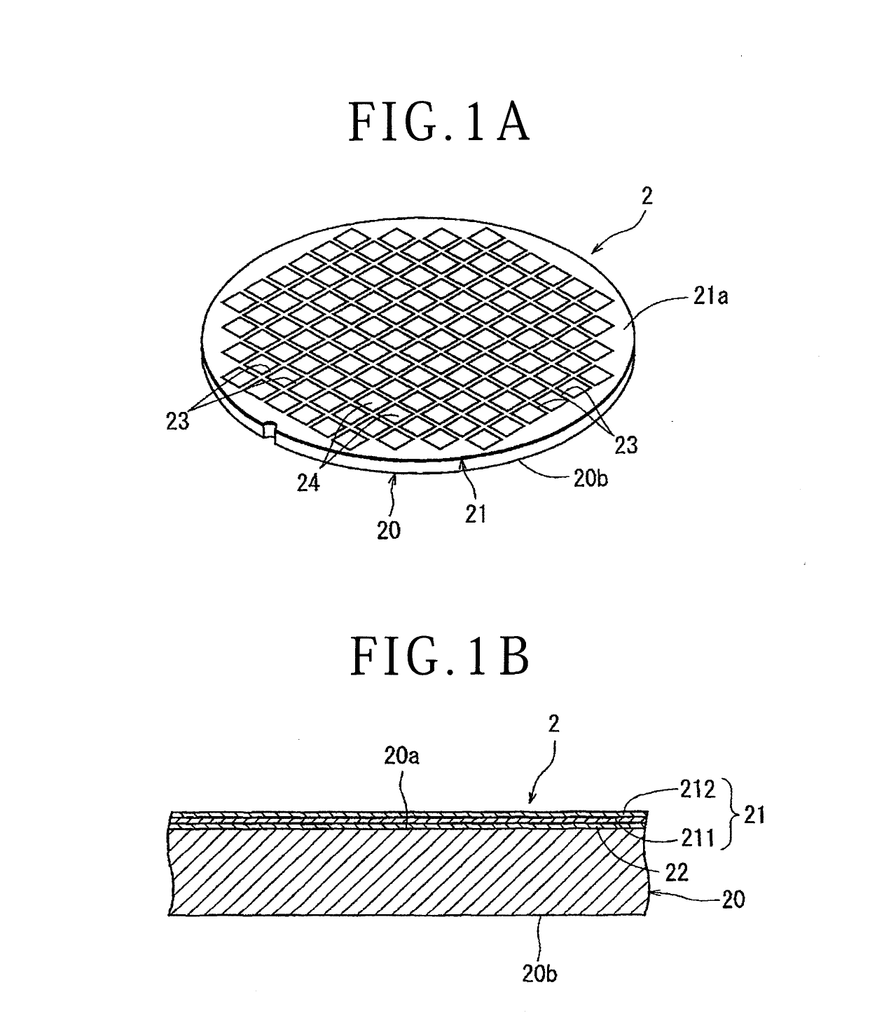

Now, preferred embodiments of the method of processing an optical device wafer according to the present invention will be described in detail below, referring to the attached drawings. FIGS. 1A and 1B show a perspective view of an optical device wafer to be processed by the method of processing an optical device wafer according to the present invention and a sectional view showing, in an enlarged form, an essential part of the optical device wafer. The optical device wafer 2 shown in FIG. 1A has a structure in which an optical device layer 21 composed of an n-type gallium nitride semiconductor layer 211 and a p-type gallium nitride semiconductor layer 212 is formed, by epitaxial growth process, over a surface 20a of a substantially circular disc-shaped sapphire substrate 20. Incidentally, in stacking the optical device layer 21 composed of the n-type gallium nitride semiconductor layer 211 and the p-type gallium nitride semiconductor layer 212 over the surface of the sapphire substrate 20 by the epitaxial growth process, a buffer layer 22 is formed between the surface 20a of the sapphire substrate 20 and the n-type gallium nitride semiconductor layer 211 constituting the optical device layer 21. Incidentally, the optical device layer 21 is not limited to a layer of gallium nitride (GaN), but may be formed of GaP, GaInP, GaInAs, GaInAsP, InP, InN, InAs, AlN, AlGaAs or the like. In addition, the buffer layer 22 is formed of the same kind of semiconductor as that forming the optical device layer. The optical device wafer 2 thus configured has, in the embodiment shown in the drawings, a structure in which the sapphire substrate 20 has a diameter of 50 mm and a thickness of 600 μm, the buffer layer 22 has a thickness of 1 μm, and the optical device layer 21 has a thickness of 10 μm. Incidentally, as shown in FIG. 1A, the optical device layer 21 has optical devices 24 formed in a plurality of regions demarcated by a plurality of streets 23 formed in a grid pattern.

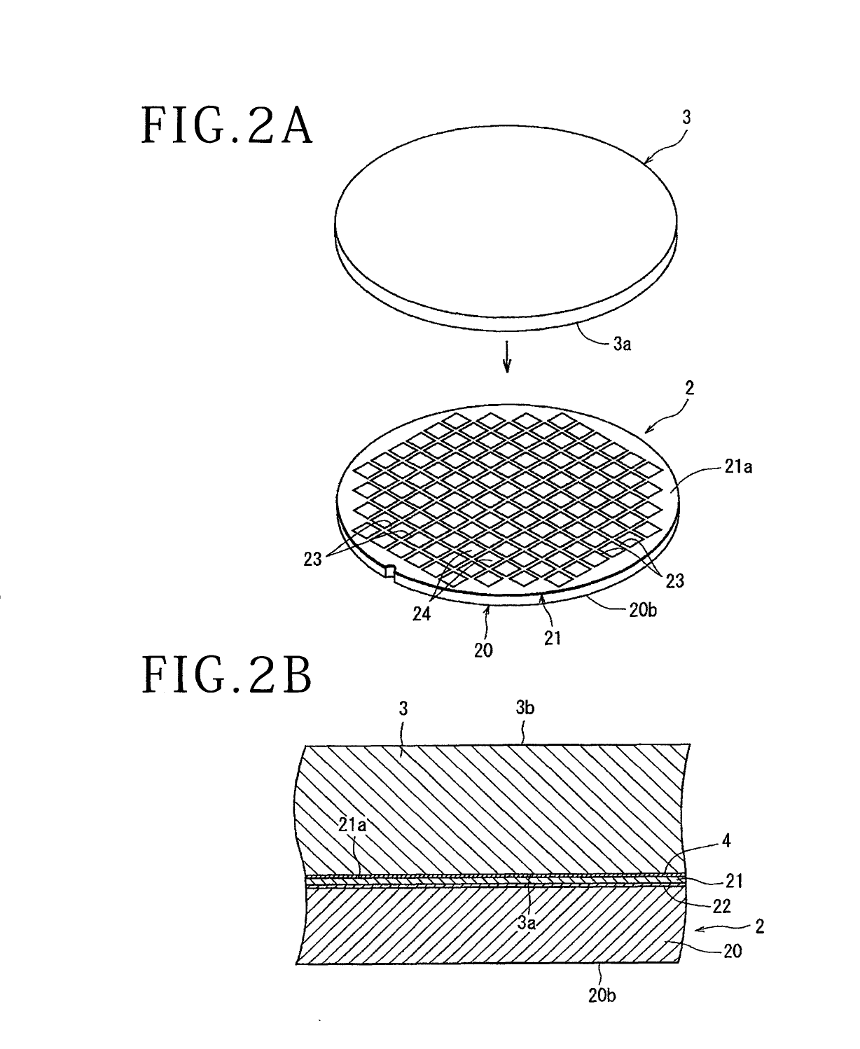

In order to peel the sapphire substrate 20 of the optical device wafer 2 from the optical device layer 21 and transfer the optical device layer 21 onto a transfer substrate as above-mentioned, a transfer substrate joining step of joining the transfer substrate to the surface 21a of the optical device layer 21 is carried out. Specifically, as shown in FIGS. 2A and 2B, the transfer substrate 3 composed of a copper substrate is joined, through a joint metal layer 4 formed of gold-tin, to the surface 21a of the optical device layer 21 formed over the surface 20a of the sapphire substrate 20 constituting the optical device wafer 2. The transfer substrate joining step is performed as follows. The joint metal is evaporated onto the surface 21a of the optical device layer 21 formed on the surface 20a of the sapphire substrate 20 or onto the surface 3a of the transfer substrate 3, to form the joint metal layer 4 having a thickness of around 3 μm. The joint metal layer 4 is opposed to the surface 3a of the transfer substrate 3 or the surface 21a of the optical device layer 21, followed by contact bonding, whereby the surface 3a of the transfer substrate 3 can be joined through the joint metal layer 4 to the surface 21a of the optical device layer 21 constituting the optical device wafer 2. Incidentally, the transfer substrate 3 is set to have a diameter of 50 mm and a thickness of 1 mm.

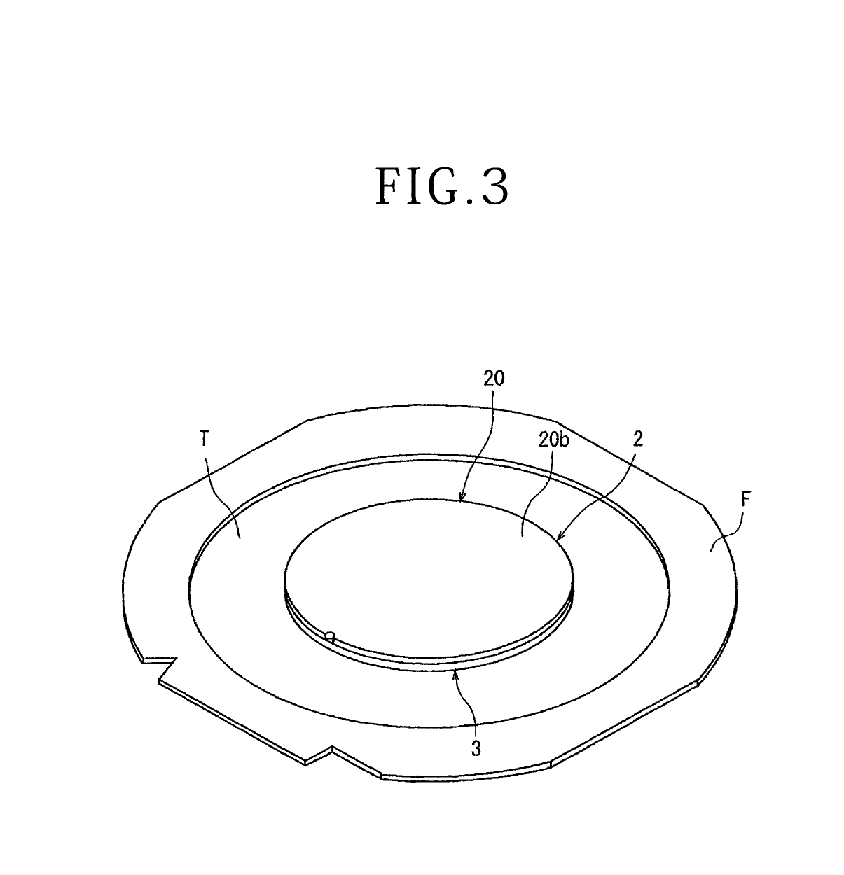

After the above-mentioned transfer substrate joining step is conducted, a transfer substrate adhering step is carried out wherein the transfer substrate 3 composed of copper substrate and joined to the surface 21a of the optical device layer 21 formed over the surface 20a of the sapphire substrate 20 constituting the optical device wafer 2 is adhered to a surface of a pressure sensitive adhesive tape mounted to an annular frame. More specifically, as shown in FIG. 3, the back surface 3b of the transfer substrate 3 joined to the surface 21a of the optical device layer 21 constituting the optical device wafer 2 is adhered to a surface of the pressure sensitive adhesive tape T having a sheet of synthetic resin such as polyolefin and mounted to the annular frame F. Accordingly, of the optical device wafer 2 having joined thereto the transfer substrate 3 adhered to the surface of the pressure sensitive adhesive tape T, the sapphire substrate 20 is located on the upper side.

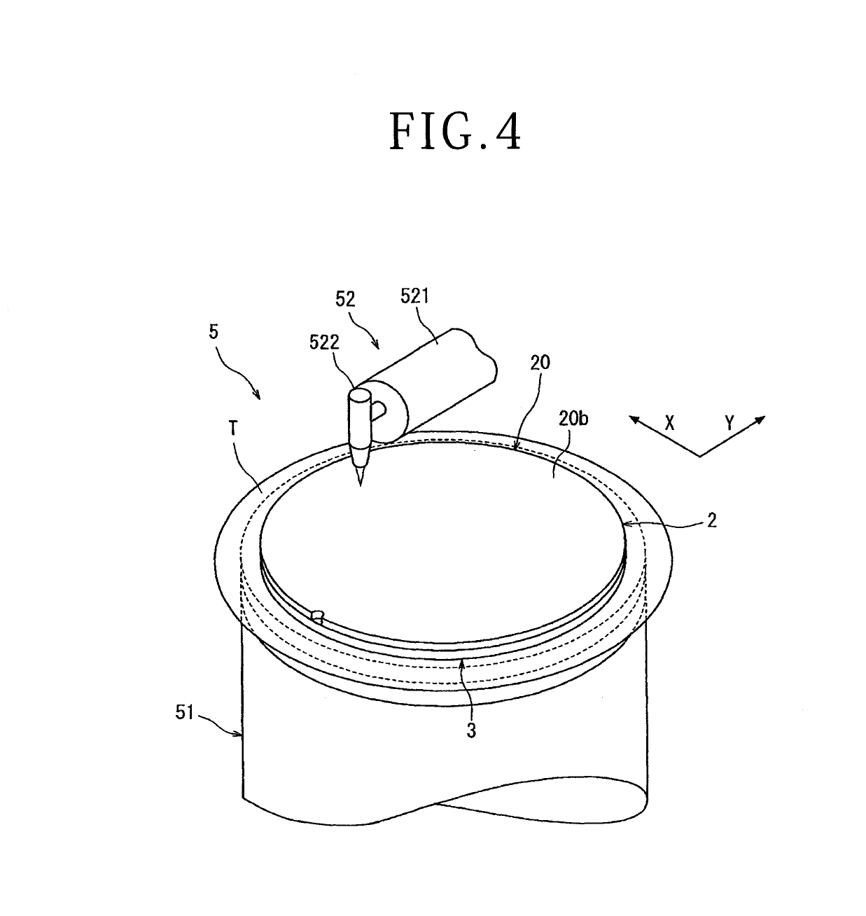

After the above-mentioned transfer substrate adhering step is performed, a buffer layer breaking step is carried out wherein the buffer layer 22 is broken by irradiating with a pulsed laser beam from the side of the sapphire substrate 20 of the optical device wafer 2 with the transfer layer 3 adhered to the surface of the optical device layer 21. The buffer layer breaking step is, in the embodiment shown in the drawings, carried out by use of a laser beam processing apparatus 5 shown in FIG. 4. The laser beam processing apparatus 5 includes a chuck table 51 for holding a work, and laser beam irradiation means 52 for irradiating the work held on the chuck table 51 with a pulsed laser beam.

The chuck table 51 holds the work on a holding surface (which is an upper surface) thereof by suction. The chuck table 51 is put to processing feed in the direction of arrow X in FIG. 4 by processing feeding means (not shown), and is put to indexing feed in the direction of arrow Y in FIG. 4 by indexing feeding means (not shown).

The laser beam irradiation means 52 includes a cylindrical casing 521 disposed substantially horizontally. In the casing 521 is housed pulsed laser beam oscillation means having a pulsed laser beam oscillator and repetition frequency setting means, which are not shown. A condenser 522 for condensing a pulsed laser beam oscillated from the pulsed laser beam oscillation means is mounted to a tip portion of the casing 521.

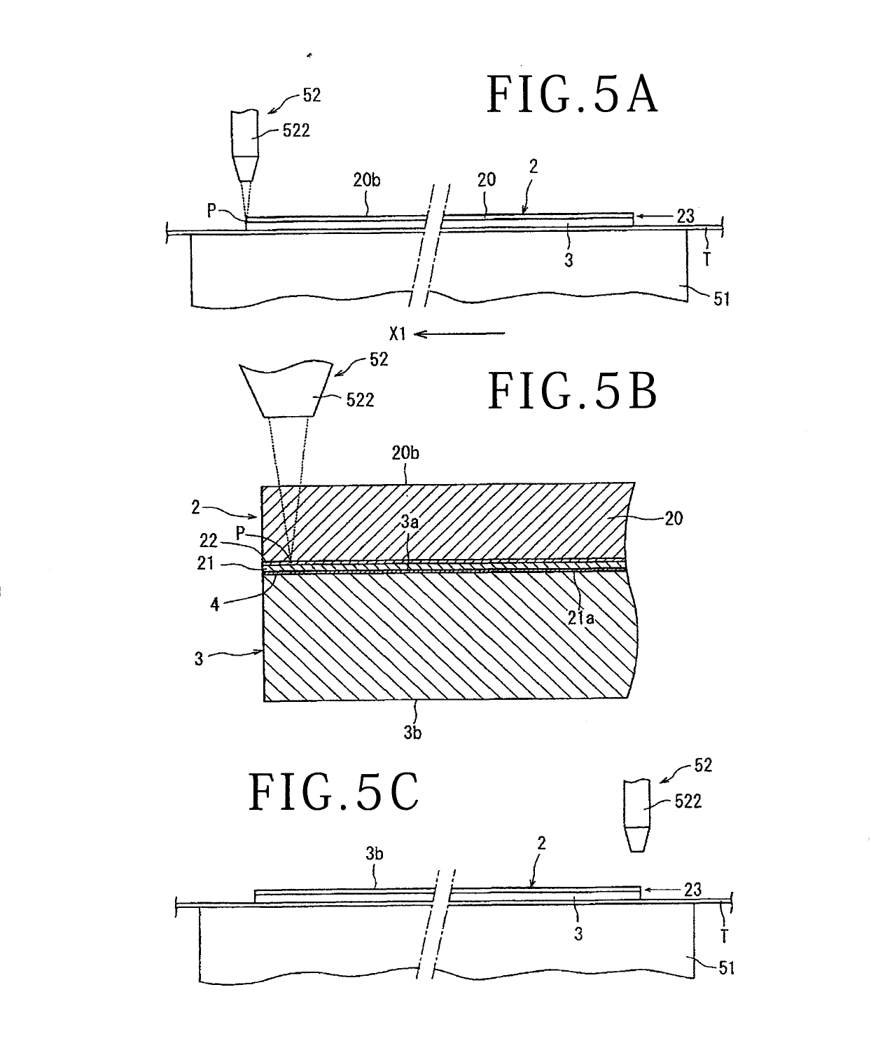

The buffer layer breaking step carried out by use of the laser beam processing apparatus 5 as above-mentioned will be described referring to FIG. 4 and FIGS. 5A to 5C. In order to perform the buffer layer breaking step, first, as shown in FIG. 4, the pressure sensitive adhesive tape, to which the transfer substrate 3 joined to the optical device wafer 2 is adhered as above-mentioned, is brought into contact with the upper surface of the chuck table 51 of the laser beam processing apparatus. Then, suction means (not shown) is operated, to hold the optical device wafer 2 onto the chuck table 51 by suction. Accordingly, of the optical device wafer 2 held on the chuck table 51, the back surface 20b of the sapphire substrate 20 is located on the upper side. Incidentally, while the annular frame F to which the pressure sensitive adhesive tape T is adhered is omitted in FIG. 4, the annular frame F is held by appropriate frame holding means disposed at the chuck table 51.

After the optical device wafer 2 with the transfer substrate 3 joined thereto is held on the chuck table 51 by suction as above-mentioned, the chuck table 51 is moved into a laser beam irradiation region in which the condenser 522 of the laser beam irradiation means 52 is located, as shown in FIG. 5A, and one end (the left end in FIG. 5A) of the sapphire substrate 20 is positioned directly under the condenser 522 of the laser beam irradiation means 52. Next, the condensing point P of the pulsed laser beam radiated from the condenser 522 is adjusted to the buffer layer 22, as shown in FIG. 5B. Then, while radiating the pulsed laser beam from the condenser 522 by operating the laser beam irradiation means 52, the chuck table 51 is moved at a predetermined processing feed velocity in a processing feed direction indicated by arrow X1 in FIG. 5A. When the other end (the right end in FIG. 5C) of the sapphire substrate 20 has arrived at the irradiation position of the condenser 522 of the laser beam irradiation means 52 as shown in FIG. 5C, the irradiation with the pulsed laser beam is stopped, and the movement of the chuck table 51 is stopped (buffer layer breaking step). This buffer layer breaking step is applied to the whole surface area of the buffer layer 22. As a result, the buffer layer 22 is broken, and the function of bonding the sapphire substrate 20 and the optical device layer 21 to each other by the buffer layer 22 is lost.

The processing conditions in the above-mentioned buffer layer breaking step are set, for example, as follows.

Light source: YAG laser

Wavelength: 257 nm

Repetition frequency: 50 kHz

Mean output: 0.12 W

Pulse width: 100 ps

Spot diameter: φ70 μm

Defocus: 1.0 mm (the condenser is moved by 1 mm toward the sapphire substrate, in the condition where the laser beam is positioned on the surface of the sapphire substrate)

Processing feed velocity: 600 mm/sec

When the buffer layer breaking step is carried out under the above-mentioned processing conditions, the pulsed laser beam with a spot diameter of φ70 μm has a spot interval of 12 μm and a spot overlapping rate of 83%, in irradiating the optical device layer 21 therewith. Incidentally, while an example wherein the chuck table 51 suction-holding thereon the optical device wafer 2 with the transfer substrate 3 joined thereto is moved rectilinearly in the processing feed direction while radiating the pulsed laser beam from the condenser 522 by operating the laser beam irradiation means 52 has been shown in the above-mentioned buffer layer breaking step, the chuck table 51 may be moved in the processing feed direction or the indexing feed direction while being rotated so that irradiation with the pulsed laser beam takes place in a spiral pattern.

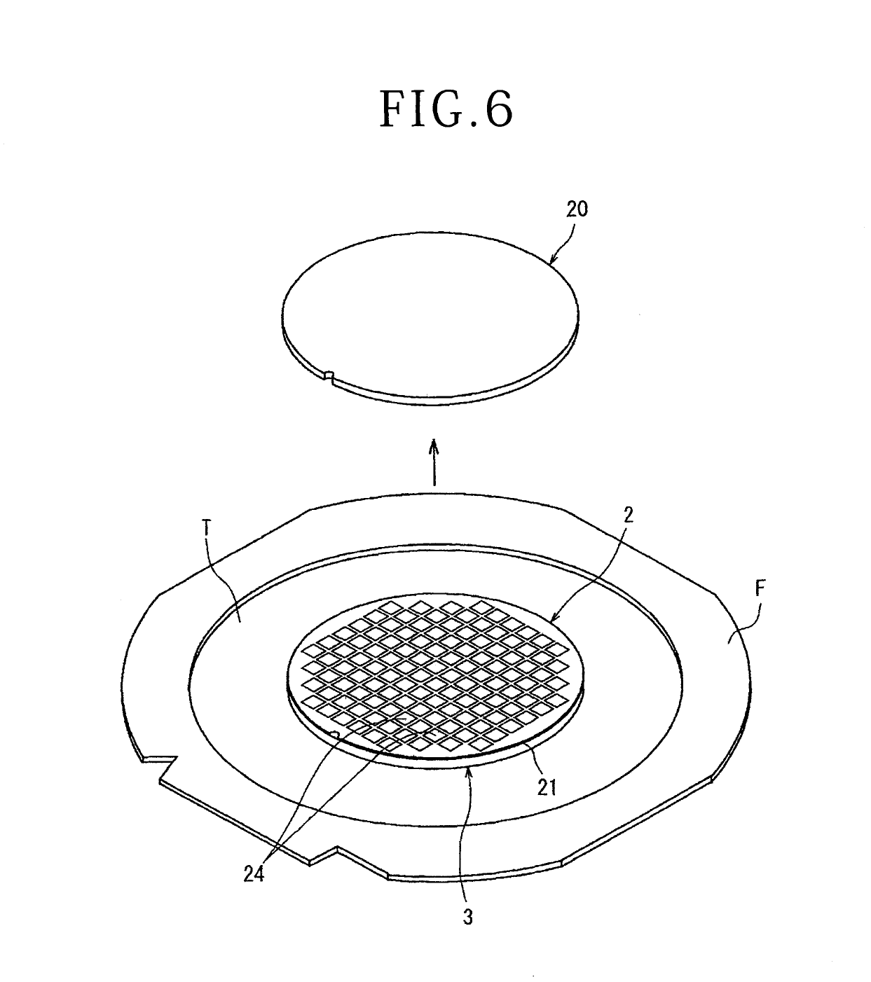

After the above-mentioned buffer layer breaking step is performed, a sapphire substrate peeling step is carried out wherein the sapphire substrate 20 is peeled from the optical device layer 21. Specifically, since the buffer layer 22 bonding the sapphire substrate 20 and the optical device layer 21 to each other has been broken, and its bonding function lost, by the buffer layer breaking step, the sapphire substrate 20 can be easily peeled from the optical device layer 21, as shown in FIG. 6.

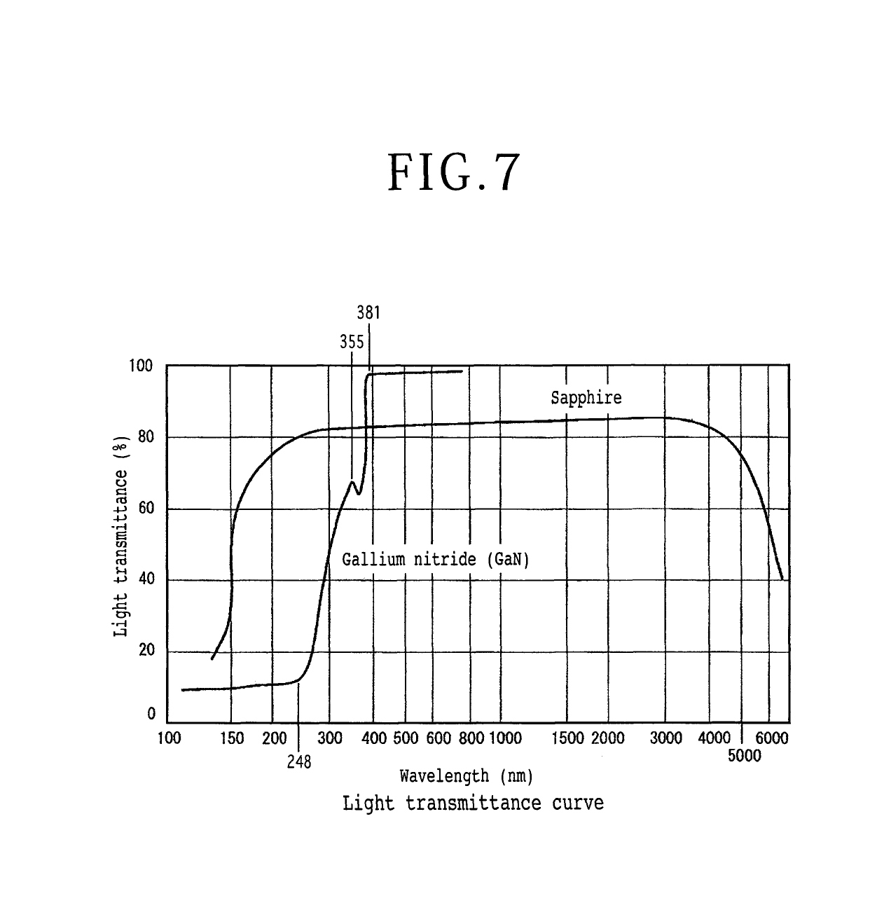

Now, the wavelength of the pulsed laser beam for irradiation therewith in the above-mentioned buffer layer breaking step will be described. It is important for the wavelength of the pulsed laser beam for irradiation therewith in the buffer layer breaking step to be set longer than an absorption edge of the sapphire substrate and shorter than an absorption edge of the buffer layer. In other words, it is necessary for the wavelength of the pulsed laser beam for irradiation therewith in the buffer layer breaking step to be such that the laser beam is transmitted through the sapphire substrate to reach the buffer layer and be absorbed by the buffer layer, whereby the buffer layer can be broken. FIG. 7 shows a graph showing light transmittance curves of sapphire and gallium nitride (GaN). In FIG. 7, wavelength (nm) is taken on the axis of abscissas, and light transmittance (%) on the axis of ordinates. As shown in FIG. 7, the absorption edge of the sapphire is 150 nm, and the absorption edge of gallium nitride (GaN) is 355 nm. Where the buffer layer is formed of gallium nitride (GaN), therefore, the wavelength of the pulsed laser beam for irradiation therewith in the buffer layer breaking step is preferably set in the range of 150 to 355 nm, and more preferably in the range of 150 to 250 nm, where the light transmittance (%) of the gallium nitride (GaN) is low. Incidentally, absorption edges of other substances which may be used to form the buffer layer are: around 270 nm for InAs; around 280 nm for AlN; around 380 nm for InP; and around 350 nm for AlGaAs.

In the next place, the pulse width of the pulsed laser beam for irradiation therewith in the buffer layer breaking step will now be described. It is important for the pulse width of the pulsed laser beam for irradiation therewith in the buffer layer breaking step to be so set that thermal diffusion length will be not more than 200 nm. With the pulse width so set that the thermal diffusion length will be not more than 200 nm, it is ensured that the energy of the pulsed laser beam is consumed in the buffer layer and would not damage the optical device layer. In other words, when the pulse width is so set that the thermal diffusion length will be more than 200 nm, the energy of the pulsed laser beam would not only break the buffer layer but also damage the optical device layer. Incidentally, the short thermal diffusion length of 200 nm or below ensures that the energy of the pulsed laser beam is absorbed along the boundary surface with the sapphire substrate in the range of the thermal diffusion length, so that even if the energy distribution is Gaussian distribution, equivalent processing to that in the case of a top-hat shape can be achieved. Furthermore, the short thermal diffusion length of 200 nm or below ensures that the pulsed laser beam is absorbed instantaneously on reaching the buffer layer in the range of the thermal diffusion range, so that only the buffer layer can be securely broken even if the sapphire substrate has warpage and the condensing point of the pulsed laser beam is thereby deviated from the buffer layer. In addition, the surface roughness of the buffer layer after the peeling of the sapphire substrate is at a permissible level of 100 nm or below, and, therefore, there is no need for an after-treatment such as polishing.

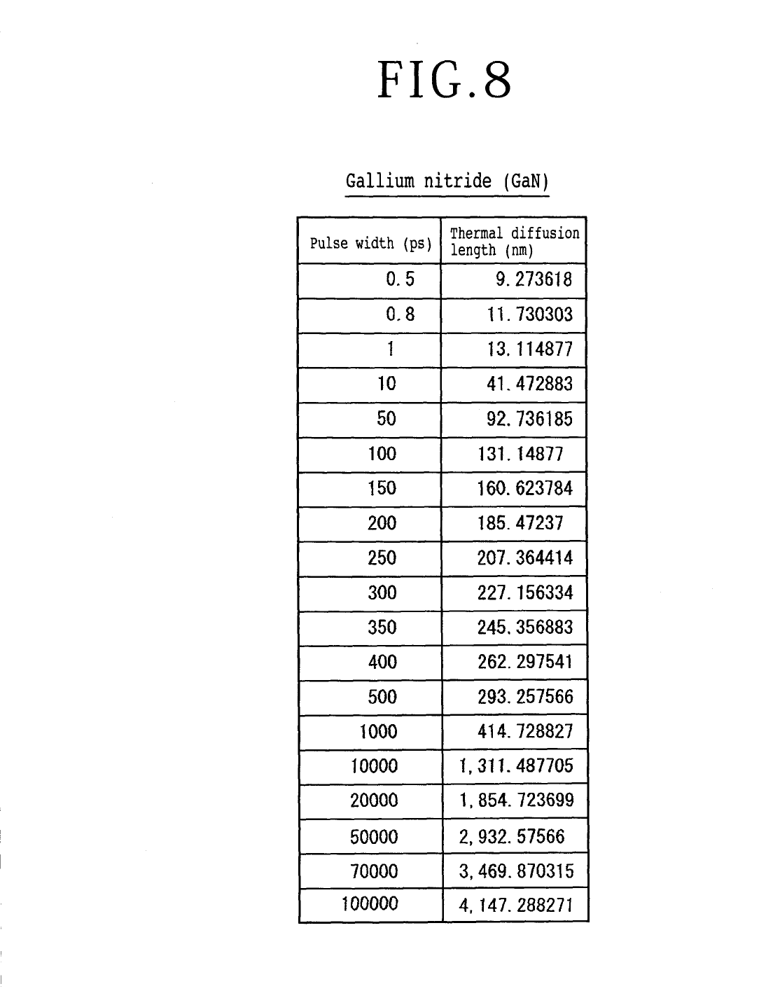

FIG. 8 shows data representing the relationship between thermal diffusion length (nm) and pulse width (ps) in gallium nitride (GaN). As shown in FIG. 8, in the case where the buffer layer is formed of gallium nitride (GaN), in order to obtain a thermal diffusion length of not more than 200 nm it is preferable to set the pulse width of the pulsed laser beam to be not more than 200 ps, and more preferably not more than 100 ps, which offers a more reduced thermal diffusion length (nm). Incidentally, the pulse widths for attaining a thermal diffusion length of not more than 200 nm in the cases of other substances which may be used to form the buffer layer are: 150 ps for GaP; 250 ps for InP; 500 ps for InAs; 50 ps for AlN; and 150 ps for AlGaAs.

Now, experimental results obtained by the present inventors will be described below.

(1) When the buffer layer is irradiated with a pulsed laser beam having a wavelength longer than 355 nm, which is the absorption edge of gallium nitride (GaN), the pulsed laser beam is transmitted through the buffer layer to damage the optical device layer, and undergoes an increased energy loss.

(2) When the buffer layer is irradiated with a pulsed laser beam having a wavelength shorter than 150 nm, which is the absorption edge of the sapphire substrate, the energy of the pulsed laser beam is absorbed by the sapphire substrate, damaging the sapphire substrate, and the energy of the pulsed laser beam reaching the buffer layer is lost more.

(3) When the buffer layer is irradiated with a pulsed laser beam having a wavelength (250 nm) corresponding to the highest absorbance of gallium nitride (GaN), processing efficiency is good, and the surface roughness of the buffer layer is not more than 50 nm.

(4) When irradiation with the pulsed laser beam is conducted with a pulse width set to 1 ns, the buffer layer can be broken assuredly, but cracks would extend to the optical device layer, damaging the optical devices.

(5) When irradiation with the pulsed laser beam is performed with a pulse width set to 500 ps, the buffer layer can be broken reliably, but the surface roughness of the buffer layer would be 500 nm, necessitating removal of the roughness by polishing. Besides, some cracks would extend to the optical device layer, damaging the optical devices.

(6) When irradiation with the pulsed laser beam is conducted with a pulse width set to 300 ps, the buffer layer can be broken assuredly, but the surface roughness of the buffer layer would be 300 nm, necessitating removal of the roughness by polishing.

(7) When irradiation with the pulsed laser beam is carried out with a pulse width set to 200 ps, the buffer layer can be broken securely. In addition, the surface roughness of the buffer layer is 100 nm, which is within the permissible range, so that polishing is not needed.

(8) When irradiation with the pulsed laser beam is performed with a pulse width set to 100 ps, the buffer layer can be broken assuredly. Besides, the surface roughness of the buffer layer is 50 nm, which is within the permissible range, so that polishing is not needed at all.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of processing an optical device wafer in which an optical device layer including an n-type semiconductor layer and a p-type semiconductor layer is stacked over a surface of a sapphire substrate, with a buffer layer therebetween, so as to peel the sapphire substrate, the method comprising:
a transfer substrate joining step of joining a transfer substrate to a surface of the optical device layer;
a buffer layer breaking step of breaking the buffer layer by irradiation with a pulsed laser beam from the sapphire substrate side of the optical device wafer with the transfer substrate joined to the surface of the optical device layer; and
a sapphire substrate peeling step of peeling off the sapphire substrate from the optical device wafer with the buffer layer broken, so as to transfer the optical device layer onto the transfer substrate,
wherein the pulsed laser beam for irradiation therewith in the buffer layer breaking step has a wavelength set to be longer than an absorption edge of the sapphire substrate and shorter than an absorption edge of the buffer layer, and a pulse width so set that a thermal diffusion length will be not more than 200 nm.

2. The method according to claim 1, wherein the buffer layer is formed of gallium nitride (GaN), and the pulse width of the pulsed laser beam for irradiation therewith in the buffer layer breaking step is set to be not more than 200 ps.

3. The method according to claim 2, wherein the pulse width of the pulsed laser beam for irradiation therewith in the buffer layer breaking step is set to be not more than 100 ps.

4. The method according to claim 2, wherein the wavelength of the pulsed laser beam for irradiation therewith in the buffer layer breaking step is set in the range of 150 to 355 nm.

5. The method according to claim 4, wherein the wavelength of the pulsed laser beam for irradiation therewith in the buffer layer breaking step is set in the range of 150 to 250 nm.
